(19) United States
(12) Patent Application Publication
(10) Pub. No.: US 2013/0341509 A1
(43) Pub. Date: Dec. 26, 2013

(54) Portable system for detecting explosive materials using near infrared hyperspectral imaging and method for using thereof

(71) Applicants: Matthew Nelson, Harrison City, PA (US); Patrick Treado, Pittsburgh, PA (US); Charles Gardner, JR., Gibsonia, PA (US)

(72) Inventors: Matthew Nelson, Harrison City, PA (US); Patrick Treado, Pittsburgh, PA (US); Charles Gardner, JR., Gibsonia, PA (US)

(73) Assignee: Chemimage Corporation, Pittsbrugh, PA (US)

(21) Appl. No.: 13/134,978

(22) Filed: Jun. 22, 2011

Related U.S. Application Data
(63) Continuation-in-part of application No. 13/068,542, filed on May 12, 2011.
Application No. 13/068,542 is a continuation-in-part of application No. 12/802,649, filed on Jun. 11, 2010.
Application No. 12/802,649 is a continuation-in-part of application No. 13/020,997, filed on Feb. 4, 2011.
Application No. 13/020,997 is a continuation-in-part of application No. 13/020,994, filed on Feb. 4, 2011.
Application No. 13/020,994 is a continuation-in-part of application No. 13/020,935, filed on Feb. 4, 2011.
Application No. 13/020,935 is a continuation-in-part of application No. 12/924,831, filed on Oct. 6, 2010.
(60) Provisional application No. 61/398,213, filed on Jun. 22, 2010.
(60) Provisional application No. 61/434,034, filed on Jan. 19, 2011.
(60) Provisional application No. 61/403,141, filed on Sep. 10, 2010.

(51) Int. Cl. G01J 5/02; H01L 31/00

(52) U.S. Cl. 250/330; 250/339.07

(57) ABSTRACT

The present disclosure provides for a portable device for detecting the presence of explosive materials, including bulk explosive materials and out-gassed by products of explosive materials. The portable device may comprise a tunable filter and a NIR detector, configured so as to generate a NIR hyperspectral image representative of a target. The portable device may also comprise a RGB detector configured to generate a video image of a region of interest. The disclosure also provides for a method of detecting explosive materials using NIR hyperspectral imaging which may comprise collecting interacted photons, passing the interacted photons through a tunable filter, and detecting the interacted photons to generate a NIR hyperspectral image representative of a target. The method may also comprise surveying a region of interest using a RGB detector to identify a target for further inspection using NIR hyperspectral imaging.

### RELATED APPLICATIONS

This application claims priority under 35 U.S.C. §119(e) to the following U.S. Provisional Patent Application Nos. 61/398,213, filed on Jun. 22, 2010, entitled “VIPIR—Near-Infrared Hyperspectral Imaging Home Made Explosives Detector”; No. 61/434,034, filed on Jan. 19, 2011, entitled “VIS-SNIR Multi-Conjugate Tunable Filter”; and No. 61/403,141, filed on Sep. 10, 2010, entitled “Systems and Methods for Improving Imaging Technology.”

This application is also a continuation-in-part of the following pending U.S. patent application Ser. Nos. 13/068,542 filed on May 12, 2011, entitled “Portable System For Detecting Hazardous Agents Using SWIR And Method For Use Thereof”; 12/802,649, filed on Jun. 11, 2010, entitled “Portable System For Detecting Explosives And A Method Of Use Thereof”; 13/020,997, filed on Feb. 4, 2011, entitled “System And Method For Detecting Explosive Agents Using SWIR, MWIR, And LWIR Hyperspectral Imaging”; 13/020,994, filed on Feb. 4, 2011, entitled “System and Method for Detection of Explosive Agents Using SWIR and MWIR Hyperspectral Imaging”; 13/020,935, filed on Feb. 4, 2011, entitled “System and Method for Detecting Hazardous Agents Including Explosives”; 12/924,831, filed on Oct. 6, 2010, entitled “System and methods for explosives detection using SWIR.” Each of above-referenced patent applications is hereby incorporated by reference in its entirety.

### BACKGROUND

Spectroscopic imaging combines digital imaging and molecular spectroscopy techniques, which can include Raman scattering, fluorescence, photoluminescence, ultraviolet, visible and infrared absorption spectroscopies. When applied to the chemical analysis of materials, spectroscopic imaging is commonly referred to as chemical imaging. Instruments for performing spectroscopic (i.e. chemical) imaging typically comprise an illumination source, image gathering optics, focal plane array imaging detectors and imaging spectrometers.

In general, the sample size determines the choice of image gathering optic. For example, a microscope is typically employed for the analysis of sub micron to millimeter spatial dimension samples. For larger objects, in the range of millimeter to meter dimensions, macro lens optics are appropriate. For samples located within relatively inaccessible environments, flexible fiberscope or rigid borescopes can be employed. For very large scale objects, such as planetary objects, telescopes are appropriate image gathering optics.

For detection of images formed by the various optical systems, two-dimensional, imaging focal plane array (FPA) detectors are typically employed. The choice of FPA detector is governed by the spectroscopic technique employed to characterize the sample of interest. For example, silicon (Si) charge-coupled device (CCD) detectors or CMOS detectors are typically employed with visible wavelength fluorescence and Raman spectroscopic imaging systems, while indium gallium arsenide (InGaAs) FPA detectors are typically employed with near-infrared spectroscopic imaging systems.

Spectroscopic imaging of a sample can be implemented by one of two methods. First, a point-source illumination can be provided on the sample to measure the spectra at each point of the illuminated area. Second, spectra can be collected over the entire area encompassing the sample simultaneously using an electronically tunable optical imaging filter such as an acousto-optic tunable filter (“AOTF”) or a LCTF. This may be referred to as “wide-field imaging”. Here, the organic material in such optical filters are actively aligned by applied voltages to produce the desired bandpass and transmission function. The spectra obtained for each pixel of such an image thereby forms a complex data set referred to as a hyperspectral image (“HSI”) which contains the intensity values at numerous wavelengths or the wavelength dependence of each pixel element in this image.

Spectroscopic devices operate over a range of wavelengths due to the operation ranges of the detectors or tunable filters possible. This enables analysis in the Ultraviolet (“UV”), visible (“VIS”), near infrared (“NIR”), short-wave infrared (“SWIR”), mid infrared (“MIR”) wavelengths and to some overlapping ranges. These correspond to wavelengths of about 180-380 nm (UV), 380-700 nm (VIS), 700-2500 nm (NIR), 900-1700 nm (SWIR), and 2500-25000 nm (MIR).

When chemicals are mixed during the making of explosive materials, the mixture may emit gaseous byproducts which can be detected by various methods. The current state of the art for detection of such explosives provides for techniques such as X-ray screening, neutron activation analysis, dogs and electronic sniffer devices. However, these techniques suffer from several disadvantages. For example, X-ray and neutron activation analysis instrumentation is generally large and immovable. Dogs and electronic sniffer devices require a close proximity to the target. Therefore, there exists a need for a mobile, agile, standoff system and method for detection of explosive materials, including gaseous byproducts.

### SUMMARY

The present disclosure relates generally to infrared hyperspectral imaging technologies for the detection of explosives and other materials. More specifically, the present disclosure provides for a relatively small (under 40 lbs and less than 2 cu. ft.), NIR HSI system, based on the spectral range from 1200 nm to 2450 nm for home made explosive (“HME”) detection. The portable device of the present disclosure holds potential for detecting the out-gassed by products of HMEs as well as bulk material on surfaces.

NIR HSI holds potential for an HME detector sensing modality. HSI combines high resolution imaging with the power of massively parallel spectroscopy to deliver images having contrast that define the composition, structure and concentration of a sample. Utilizing a liquid crystal-based imaging spectrometer, NIR images are collected as a function of wavelength, resulting in a hyperspectral datacube where contrast is indicative of the varying amounts of absorbance, reflectance or scatter associated with the various materials present in the field of view. This method yields a rapid, reagentless, nondestructive, non-contact method capable of fingerprinting trace materials in a complex background.

Specifically, this portable device will have the capability to detect the out-gassed byproducts of HMEs as well as bulk material on surfaces. The portable device and associated methods described herein overcome the limitations of the prior art by providing for the detection of explosives at appreciable standoff distances. The portable device holds potential for application by military personnel for unobtrusive, noncontact screening and detection of HME residue on the surface of buildings and vehicles, HME residue on individuals' hair, clothing and/or skin, or HME out-gassed by products, among other materials.

### BRIEF DESCRIPTION OF THE DRAWINGS

FIG. 1A is illustrative of exemplary packaging of a system of the present disclosure.

FIG. 1B is illustrative of exemplary packaging of a system of the present disclosure.

FIG. 1C is illustrative of exemplary packaging of internation components of the present disclosure.

FIG. 1D is illustrative of an exemplary detection screen of the present disclosure.

FIG. 2A is a schematic representation of a system of the present disclosure.

FIG. 2B is a schematic representation of a system of the present disclosure.

FIG. 3 is illustrative of exemplary specifications that may comprise an embodiment of a system of the present disclosure.

FIG. 4A is illustrative of a method of the present disclosure.

FIG. 4B is illustrative of a method of the present disclosure.

FIG. 5 illustrates the detection capabilities of a system of the present disclosure.

FIG. 6 illustrates the detection capabilities of a system of the present disclosure.

FIG. 7 illustrates the detection capabilities of a system of the present disclosure.

FIG. 8 illustrates the detection capabilities of a system of the present disclosure.

FIG. 9 illustrates the detection capabilities of a system of the present disclosure.

FIG. 10 illustrates the detection capabilities of a system of the present disclosure.

FIG. 11 illustrates the detection capabilities of a system of the present disclosure.

### DETAILED DESCRIPTION

The accompanying drawings, which are included to provide further understanding of the disclosure and are incorporated in and constitute a part of this specification, illustrate embodiments of the disclosure and, together with the description, serve to explain the principles of the disclosure.

The patent or application file contains at least one drawing executed in color. Copies of this patent or patent application publication with color drawing(s) will be provided by the Office upon request and payment of the necessary fee.

The present disclosure provides for a portable device and method for detecting explosives and other materials, including gaseous byproducts emitted during the making of explosives. Examples of explosive materials that may be detected using the portable device and method disclosed herein include, but are not limited to: explosives selected from the group consisting of: nitrocellulose, Ammonium nitrate (“AN”), nitroglycerin, 1,3,5-trinitroperhydro-1,3,5-triazine (“RDX”), 1,3,5,7-tetranitroperhydro-2,3,5,7-tetrazocine (“HMX”) and 1,3,-Dinitrato-2,2-bis(nitratomethyl) propane (“PETN”), and combinations thereof.

In one embodiment the present disclosure provides for a portable system for detecting explosive materials using NIR hyperspectral imaging. This portable system may be referred to commercially as the “VipiR Sensor”.

By utilizing the NIR region of the spectrum, the portable device may take advantage of the fact that ammonia-containing compounds demonstrate stronger absorbance in this spectral range. This phenomenon means that detection capability may be increased. In one embodiment, the portable device may require active cooling. The portable device design may assist in determining the optimum sensor configuration, identify characteristics and sources of key components.

In one embodiment of the present disclosure, the portable device may be configured to provide standoff detection and confirmation of explosives and/or chemicals. The portable device may be a soldier-operated, passive, handheld, standoff, wide-area surveillance sensor for the detection of explosive and chemical residue on surfaces, as well as out-gassed by products of explosive mixtures.

This sensor may be applied to at least the following operational scenarios: Interrogation of suspect vehicles (at a checkpoint, parked along the roadway or travelling freely), interrogation of suspect individuals (at a checkpoint or an unstructured crowd); interrogation of suspect facilities or areas where homemade explosive production may be taking place. The present invention holds potential for accurately detecting explosives and explosive residue in a sample scene comprising a number of materials including emplacements, urban clutter, ordnance and/or explosive residue.

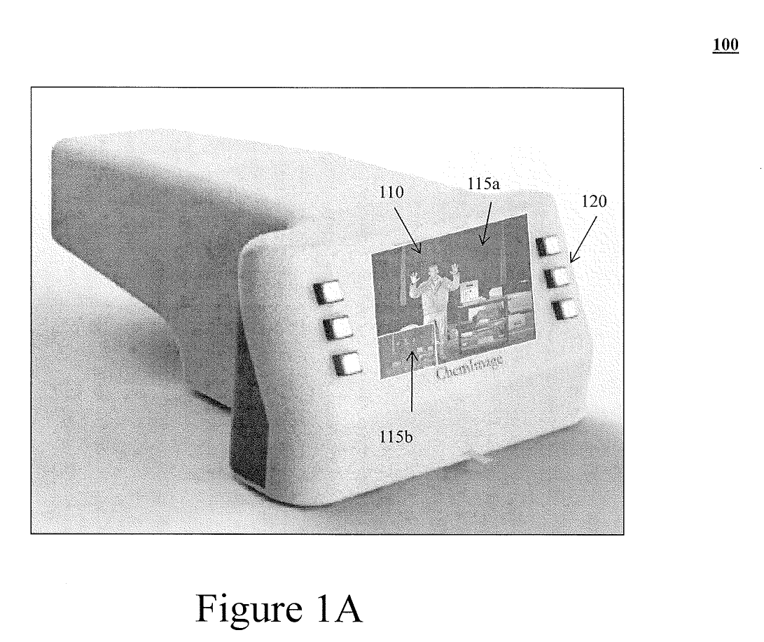

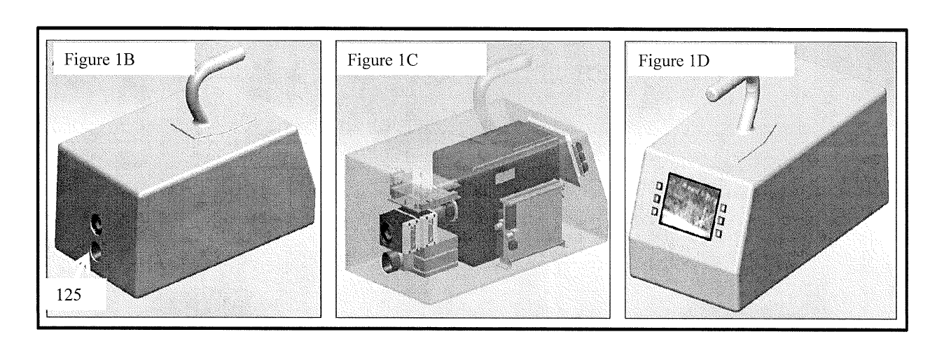

FIG. 1A is illustrative of an exemplary packaging option of one embodiment of the present disclosure. In FIG. 1A, the system 100 may comprise a display 110 and one or more user controls 120 for operating the system 100. In one embodiment, the display 110 may comprise two or more images displayed in several display modes. In one embodiment, these display modes may comprise at least one of: two images displayed simultaneously, two images displayed sequentially, and combinations thereof. Simultaneous image display is illustrated in FIG. 1A as images 115a and 115b.

FIGS. 1B-1D are illustrative of another exemplary packaging option of a system of the present disclosure. FIG. 1B, illustrates an exemplary lens placement of collection optics 125. FIG. 1C illustrates exemplary internal components, and FIG. 1D illustrates an exemplary detection screen. As illustrated in FIGS. 1A and 1B, the present disclosure contemplates a system that is small in size and may further comprise a handle or other mechanism for easy transportability.

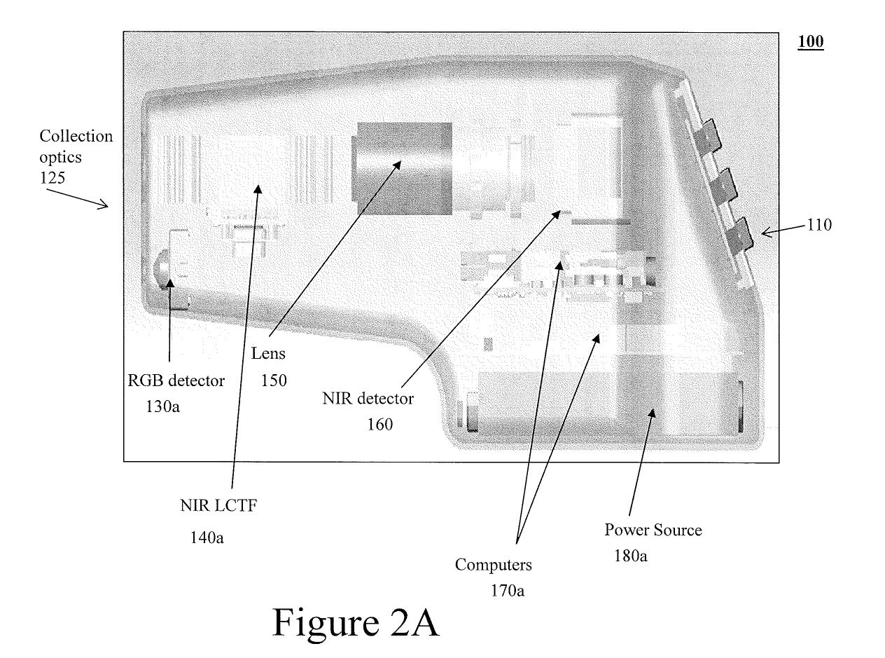

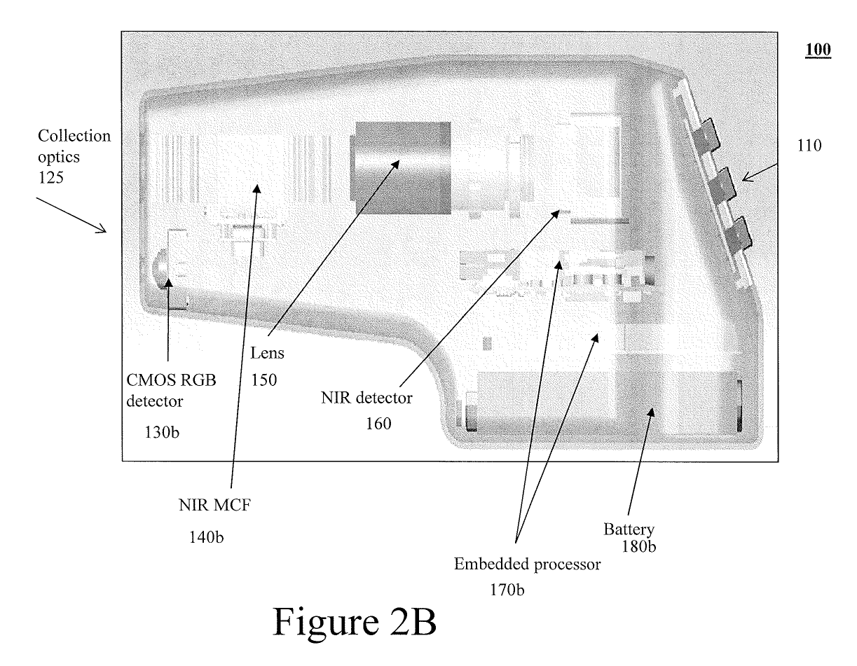

FIGS. 2A and 2B are provided to illustrate two embodiments of a system of the present disclosure. In FIG. 2A, a portable device 100 may comprise collection optics 125 for collecting at least one plurality of interacted photons. These interacted photons may comprise photons selected from the group consisting of: photons reflected by a target, photons absorbed by a target, photons scattered by a target, photons emitted by a target, and combinations thereof.

In one embodiment, at least one plurality of interacted photons may be generated by illuminating a target. This illumination may be accomplished using at least one of: active illumination, passive illumination, and combinations thereof. Active illumination may be appropriate in nighttime and/or low light conditions and may utilize a laser light source and/or broadband light source. In one embodiment, the active illumination source may be coupled to a portable device of the present disclosure. In such an embodiment, the target may be illuminated with illuminating photons emanating from said portable device. Passive illumination may be appropriate in daytime and/or bright light conditions and may utilize solar radiation and/or ambient light.

This plurality of interacted photons may be passed through a filter. In one embodiment, this filter may comprise at least one of: a tunable filter, a fixed filter, a dielectric filter, and combinations thereof. The filter may comprise an optical filter configured so as to operate in the at least one of the following NIR ranges: approximately, 900 nm-2450, approximately 1200 nm-2450 nm, and combinations thereof.

In one embodiment, this tunable filter may be selected from the group consisting of: a Fabry Perot angle tuned filter, an acousto-optic tunable filter, a liquid crystal tunable filter, a Lyot filter, an Evans split element liquid crystal tunable filter, a Solc liquid crystal tunable filter, a spectral diversity filter, a photonic crystal filter, a fixed wavelength Fabry Perot tunable filter, an air-tuned Fabry Perot tunable filter, a mechanically-tuned Fabry Perot tunable filter, a liquid crystal Fabry Perot tunable filter, and a multi-conjugate tunable filter, and combinations thereof.

In one embodiment, this tunable filter may comprise filter technology available from ChemImage Corporation, Pittsburgh, Pa. This technology is more fully described in the following U.S. Pat. Nos. 6,992,809, filed on Jan. 31, 2006, entitled “Multi-Conjugate Liquid Crystal Tunable Filter,” No. 7,362,489, filed on Apr. 22, 2008, entitled “Multi-Conjugate Liquid Crystal Tunable Filter,” No. 13/066,428, filed on Apr. 14, 2011, entitled “Short wave infrared multi-conjugate liquid crystal tunable filter.” These patents and patent applications are hereby incorporated by reference in their entireties.

In one embodiment, this multi-conjugate filter (“MCF”) may be configured with an integrated design. Such filters hold potential for increasing image quality, reducing system size, and reducing manufacturing cost. Such a design may enable integration of a filter, a camera, an optic, a communication means, and combinations thereof into an intelligent unit. This design may also comprise a trigger system configured to increase speed and sensitivity of the system. In one embodiment, this trigger may comprise a trigger TTL. The trigger may be configured so as to communicate a signal when various components are ready for data acquisition. The trigger may be configured to communicate with system components so that data is acquired at a number of sequential wavelengths. Such a design may hold potential for reducing noise. This integration may enable communication between the elements (optics, camera, filter, etc.). This communication may be between a filter and a camera, indicating to a camera when a filter ready for data acquisition.

In one embodiment, the filter may be configured with a square aperture. This square aperture configuration holds potential for overcoming the limitations of the prior art by increasing image quality and reducing system size and manufacturing costs. Such an embodiment enables the configuration of such filters to fit almost exactly on a camera, such as a CCD. This design overcomes the limitations of the prior art by providing a much better fit between a filter and a camera. This better fit may hold potential for utilizing the full CCD area, optimizing the field of view. This configuration holds potential for an optimized design wherein every pixel may have the same characteristic and enabling a high density image.

One problem with the prior art is that the camera and filter do not exactly line up, creating “dark” areas in the corners. This results in lower image quality than is possible utilizing the configuration of the present disclosure.

In one embodiment, illustrated in FIG. 2A, this tunable filter may comprise a NIR LCTF 140a. This tunable filter may be configured so as to sequentially filter the plurality of interacted photons into a plurality of predetermined wavelength bands.

The filtered photons may then be detected using a first detector, illustrated in FIG. 2A as a NIR detector 160. The filtered photons may be detected to thereby generate at least one NIR hyperspectral image representative of the target. In one embodiment, this NIR detector 160 may comprise a Stirling closed cycle cooler InSb focal plane array detector (or MCT detector). This NIR hyperspectral image may be displayed on the display 110. The NIR detector 160 may be configured for the NIR spectral range which will allow for a small form factor but will not sacrifice detection capability.

In one embodiment, the NIR detector 160 may be configured so as to generate at least one of: a NIR spectra representative of a target, a NIR image representative of a target and combinations thereof. This NIR image may comprise at least one of: a spatially accurate wavelength resolved NIR image representative of a target, a multispectral NIR image representative of a target, a hyperspectral NIR image representative of a target, and combinations thereof.

Spatially resolved NIR spectral signatures are compared to a NIR-spectral library that is compiled from known material signatures, and trained against ambient background. Positive detection obtained by comparing NIR scene to signature library may be obtained using pattern matching algorithms or other chemometric techniques.

The NIR detector 160 may be configured so as to detect said photons in the range of approximately 1200 nm-2450 nm, including the upper and lower limits of the range. In another embodiment, the detector may be configured so as to detect said photons in the range of approximately 700 nm-2500 nm, including the upper and lower limits of the range. In yet another embodiment, the detector may be configured so as to detect said photons in the rage of 900 nm-2450 nm, including the upper and lower limits of the range. In one embodiment, this NIR detector may comprise a focal plane array detector. In one embodiment, this focal plane array may comprise a cooled detector. This focal plane array detector may comprise at least one of: an InGaAs focal plane array detector, an InSb focal plane array detector, a MCT focal plane array detector, and combinations thereof.

The portable device 100 may further comprise one or more computers 170a which may be configured to control the portable device and/or store information such as test data, reference databases and other information. These reference databases may comprise reference NIR and/or other data that may be consulted to determine the presence or absence of a hazardous agent on a target. In one embodiment, these reference NIR data may comprise at least one of reference image and reference spectra, which may be stored in the memory of the device itself. In another embodiment, the device may also be configured for remote communication with a host station using a wireless link to report important findings or update its reference library. The device 100 may comprise at least one power source 180a for powering the portable device.

In one embodiment, the portable device 100 may further comprise a second detector which may operate in a modality other than NIR. In the embodiment of FIGS. 2A and 2B, this second detector may comprise a RGB detector 130a. This RGB detector 130a may be configured so as to generate a RGB image of the target. It is also contemplated by the present disclosure that portable device 100 may be configured to operate in a surveying mode, surveying an area of interest for potential targets. In such an embodiment, data collected using the RGB detector 130a may be analyzing to identify a target for further interrogation using NIR hyperspectral imaging. In one embodiment, the RGB image may comprise a RGB video image. Such an embodiment holds potential for dynamic data capture while operating in a stationary and/or on-the-move modality.

FIG. 2B illustrates another embodiment of the portable system 100. In such an embodiment, the RGB detector 130a of FIG. 2A may comprise a CMOS RGB detector 130b. The NIR LCTF 140a of FIG. 2A may comprise a NIR MCF 140b. The MCF is a type of LCTF which consists of a series of stages composed of polarizers, retarders, and liquid crystals. The MCF is capable of providing diffraction limited spatial resolution, and a spectral resolution consistent with a single stage dispersive monochromator. The MCF may be computer controlled, with no moving parts, and may be tuned to any wavelength in the given filter range. This results in the availability of hundreds of spectral bands. In one embodiment, the individual liquid crystal stages are tuned electronically and the final output is the convolved response of the individual stages. The MCF holds potential for higher optical throughput, superior out-of-band rejection and faster tuning speeds. The computer 170a of FIG. 2A may comprise one or more embedded processors 170b. Embedded processor technology holds potential for real-time processing and decision-making. The use of a MCF and embedded processor technology holds potential for achieving faster wavelength switching, image capture, image processing and explosives detection. And, a power source 180a may comprise a battery 180b.

In one embodiment, the device 100 may further comprise one or more communication ports for electronically communicating with other electronic equipments such as a server or printer. In one embodiment, such communication may be used to communicate with a reference database or library comprising at least one of: a reference spectra corresponding to a known material and a reference NIR spectroscopic image representative of a known material. In such an embodiment, the device may be configured for remote communication with a host station using a wireless link to report important findings or update its reference library.

The present disclosure contemplates a quick analysis time, measured in terms of seconds. For example, various embodiments may contemplate analysis time in the order of <10 seconds, <5 seconds, and <2 seconds. Therefore, the present disclosure contemplates substantially simultaneous acquisition and analysis of spectroscopic images. In one embodiment, the sensor may be configured to operate at speeds of up to 15-20 mph. One method for dynamic chemical imaging is more fully described in U.S. Pat. No. 7,046,359, filed on Jun. 30, 2004, entitled “System and Method for Dynamic Chemical Imaging”, which is hereby incorporated by reference in its entirety.

The device 100 may comprise embedded system parallel processor technology for real-time processing and decision-making that may be implemented in a device of the present disclosure. In one embodiment, this embedded processor technology may comprise Hyper-X embedded processor technology.

In one embodiment of the present disclosure, the portable device comprises a lens suitable for use in a portable device. The use of a smaller lens (as opposed to a telescope lens that may be found in a larger system) allows for the system's small size. In one embodiment, the device may comprise a fixed focal length optic. The present disclosure also contemplates the use of a smaller camera format (in one embodiment a smaller sized 640×512 pixel camera). The present disclosure also contemplates the use of an embedded processor to reduce the size of the computer and increase speed.

In one embodiment of the present disclosure, the portable system 100 VipIR may incorporate a high pixel resolution, high-frame rate color video camera system to assist in locating targets of interest. The NIR HSI portion of the portable device may comprise an InSb or MCT focal plane camera coupled to a wavelength-agile LCTF or MCF in combination with a fixed focal length lens and an embedded processor. In one embodiment, this may be a Hyper-X multi-core embedded processor.

In one embodiment, a portable device of the present disclosure may be configured so as to filter interacted photons in one of the following modalities: sequentially, simultaneously, and combinations thereof. The present disclosure contemplates that in one embodiment, interacted photons may be filtered sequentially by a tunable filter. In another embodiment, the present disclosure contemplates that dual polarization techniques and/or Fiber Array Spectral Translator (“FAST”) technology may be incorporated into the portable device and associated methods described herein to facilitate simultaneous filtering of interacted photons. In one embodiment, the dual polarization technology may comprise that available from ChemImage Corporation, Pittsburgh, Pa. This technology is more fully described in pending U.S. Patent Application No.: US 2011/0012916, filed on Apr. 20, 2010, entitled “System and method for component discrimination enhancement based on multispectral addition imaging,” which is hereby incorporated by reference in its entirety.

The present disclosure contemplates that dual polarization techniques and/or FAST technology may be incorporated into the portable device and associated methods described herein to facilitate simultaneous filtering of interacted photons. In one embodiment, the dual polarization technology may comprise that available from ChemImage Corporation, Pittsburgh, Pa. This technology is more fully described in pending U.S. Patent Application No.: US 2011/0012916, filed on Apr. 20, 2010, entitled “System and method for component discrimination enhancement based on multispectral addition imaging,” which is hereby incorporated by reference in its entirety.

In one embodiment, the disclosure relates to a portable system having a fiber array spectral translator (“FAST”) for obtaining a spatially accurate wavelength-resolved image of a target having a first and a second spatial dimension that can be used for the detection of explosive materials. In one embodiment, a FAST system may comprise a two-dimensional array of optical fibers drawn into a one-dimensional fiber stack so as to effectively convert a two-dimensional field of view into a curvilinear field of view, and wherein said two-dimensional array of optical fibers is configured to receive said photons and transfer said photons out of said fiber array spectral translator device and to at least one of: a spectrograph/spectrometer, a filter, a detector, and combinations thereof.

The FAST system can provide faster real-time analysis for rapid detection, classification, identification, and visualization of, for example, explosive materials, hazardous agents, biological warfare agents, chemical warfare agents, and pathogenic microorganisms, as well as non-threatening objects, elements, and compounds. FAST technology can acquire a few to thousands of full spectral range, spatially resolved spectra simultaneously, This may be done by focusing a spectroscopic image onto a two-dimensional array of optical fibers that are drawn into a one-dimensional distal array with, for example, serpentine ordering. The one-dimensional fiber stack is coupled to an imaging spectrograph. Software may be used to extract the spectral/spatial information that is embedded in a single CCD image frame.

One of the fundamental advantages of this method over other spectroscopic methods is speed of analysis. A complete spectroscopic imaging data set can be acquired in the amount of time it takes to generate a single spectrum from a given material. FAST can be implemented with multiple detectors. Color-coded FAST spectroscopic images can be superimposed on other high-spatial resolution gray-scale images to provide significant insight into the morphology and chemistry of the sample.

The FAST system allows for massively parallel acquisition of full-spectral images. A FAST fiber bundle may feed optical information from is two-dimensional non-linear imaging end (which can be in any non-linear configuration, e.g., circular, square, rectangular, etc.) to its one-dimensional linear distal end. The distal end feeds the optical information into associated detector rows. The detector may be a CCD detector having a fixed number of rows with each row having a predetermined number of pixels. For example, in a 1024-width square detector, there will be 1024 pixels (related to, for example, 1024 spectral wavelengths) per each of the 1024 rows.

The construction of the FAST array requires knowledge of the position of each fiber at both the imaging end and the distal end of the array. Each fiber collects light from a fixed position in the two-dimensional array (imaging end) and transmits this light onto a fixed position on the detector (through that fiber's distal end).

Each fiber may span more than one detector row, allowing higher resolution than one pixel per fiber in the reconstructed image. In fact, this super-resolution, combined with interpolation between fiber pixels (i.e., pixels in the detector associated with the respective fiber), achieves much higher spatial resolution than is otherwise possible. Thus, spatial calibration may involve not only the knowledge of fiber geometry (i.e., fiber correspondence) at the imaging end and the distal end, but also the knowledge of which detector rows are associated with a given fiber.

In one embodiment, the portable device may comprise FAST technology available from ChemImage Corporation, Pittsburgh, Pa. This technology is more fully described in the following U.S. Patents, hereby incorporated by reference in their entireties: U.S. Pat. No. 7,764,371, filed on Feb. 15, 2007, entitled “System And Method For Super Resolution Of A Sample In A Fiber Array Spectral Translator System”; U.S. Pat. No. 7,440,096, filed on Mar. 3, 2006, entitled “Method And Apparatus For Compact Spectrometer For Fiber Array Spectral Translator”; U.S. Pat. No. 7,474,395, filed on Feb. 13, 2007, entitled “System And Method For Image Reconstruction In A Fiber Array Spectral Translator System”; and U.S. Pat. No. 7,480,033, filed on Feb. 9, 2006, entitled “System And Method For The Deposition, Detection And Identification Of Threat Agents Using A Fiber Array Spectral Translator”.

The embodiments of FIGS. 2A and 2B are configured for passive illumination (i.e., solar radiation). However, a laser or other illumination source may also be included in the device to provide for active illumination. In one embodiment, the device may further comprise one or more communication ports for electronically communicating with other electronic equipments such as a server or printer. In one embodiment, such communication may be used to communicate with a reference database or library comprising at least one of: a reference spectra corresponding to a known explosive material and a reference NIR hyperspectral image representative of a known explosive material. In such an embodiment, the device may be configured for remote communication with a host station using a wireless link to report important findings or update its reference library. In another embodiment, this reference database may be stored in the memory of the device itself.

In one embodiment of the present disclosure, NIR hyperspectral imaging may be achieved using a sensor mounted to a vehicle for OTM detection. In another embodiment, the sensor may be mounted to a platform for stationary surveillance and detection. This embodiment provides for standoff detection and may be used in EOD, route clearance, tactical and convoy operations. In one embodiment, the device may be configured to provide detection performance at ranges of up to 20 m standoff distance, which includes high probability of detection (P_{D}) and low false alarm rate (FAR). The system may operate traveling at speeds of up to 45 mph, for screening frequently traveled routes or villages.

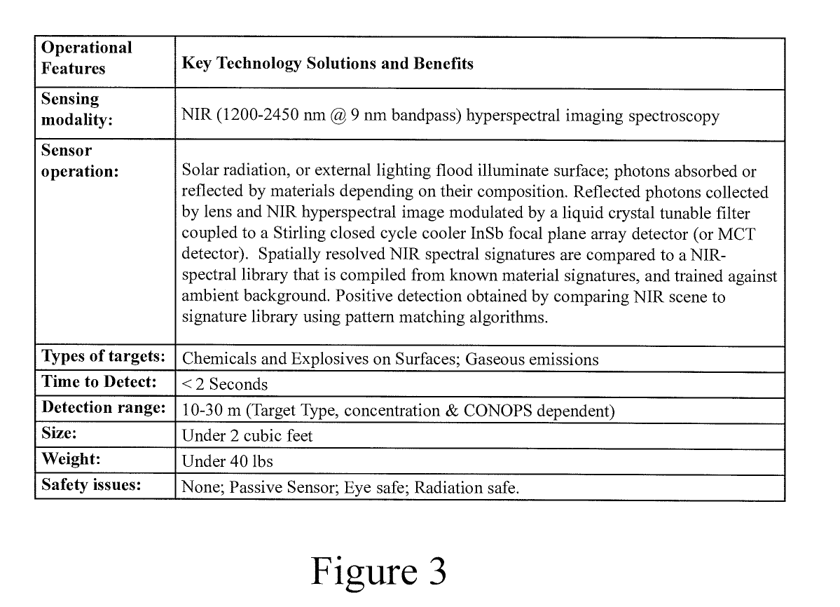

FIG. 3 is provided to illustrate exemplary technical specifications of a portable device of the present disclosure. FIG. 3 is illustrative of one embodiment of the present disclosure and it is contemplated herein that other embodiments with similar specifications may be configured. Based on the specifications of the chosen detector and lens combination, one embodiment of the portable device may operate over the range of 900-2450 nm. The unique advantages of the present disclosure may center on the usage of multiple technologies. The combination of both spectral and image processing techniques to take advantage of the characteristics of the scene hold potential for detection of targets of interest while minimizing false positives. A simple interface that gives a user the ability to make rapid and intuitive decisions may be implemented into the portable device as a key component. This component may be achieved using software.

The present disclosure also provides for a method for detecting explosive materials. In one embodiment, this method may comprise: collecting a first plurality of interacted photons using a portable device, wherein said first plurality of interacted photons are selected from the group consisting of: photons absorbed by a target, photons reflected by a target, photons scattered by a target, photons emitted by a target and combinations thereof; passing said first plurality of interacted photons through a filter; detecting said first plurality of interacted photons using said portable device to thereby generate a test NIR hyperspectral image representative of said target; analyzing said test NIR hyperspectral image to thereby identify said target as comprising at least one explosive material, wherein said explosive material comprises at least one of: a bulk explosive material, a gaseous byproduct of an explosive material, and combinations thereof.

In one embodiment, the filter may comprise at least one of: a tunable filter, a fixed filter, a dielectric filter, and combinations thereof. In one embodiment, the first plurality of interacted photons may be filtered in one of the following modalities: sequentially, simultaneously, and combinations thereof.

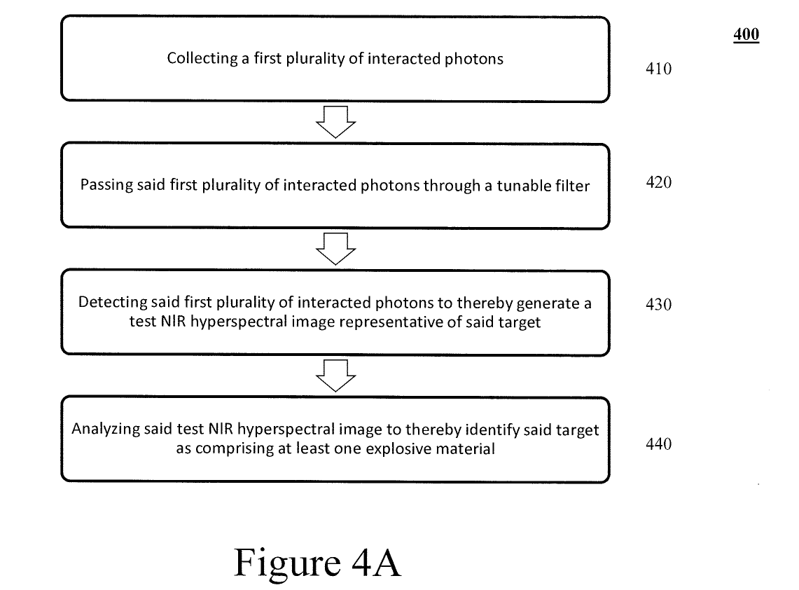

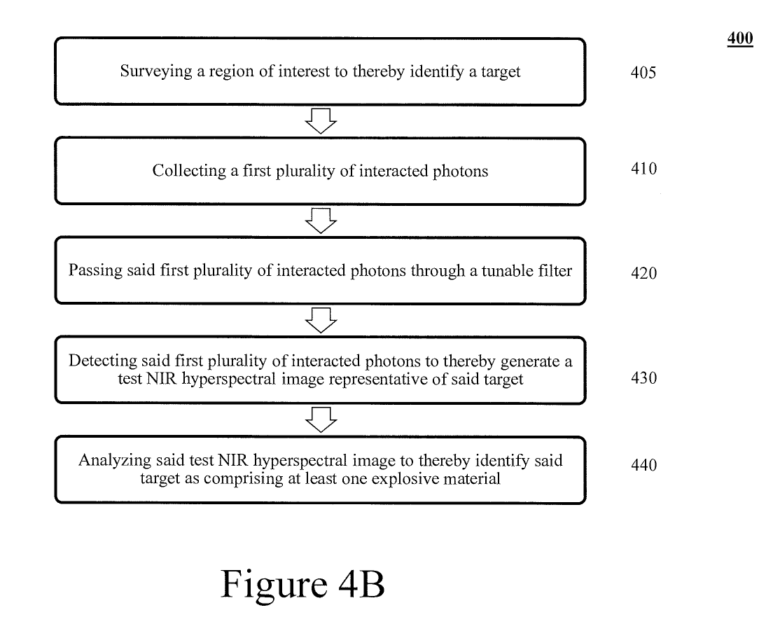

One embodiment is illustrated by FIG. 4A. In such an embodiment, the method 400 may comprise collecting a first plurality of interacted photons in step 410. This first plurality of interacted photons may comprise photons absorbed by a target, photons reflected by a target, photons scattered by a target, photons emitted by a target, and combinations thereof. This first plurality of interacted photons may be generated by illuminating a target using at least one of active illumination, passive illumination, and combinations thereof.

This first plurality of interacted photons may be passes through a tunable filter in step 420. In one embodiment, this tunable filter may be configured so as to sequentially separate said first plurality of interacted photons into a plurality of predetermined wavelength bands. This first plurality of interacted photons may then be detected in step 430 to thereby generate a test NIR hyperspectral image representative of a target. This test NIR hyperspectral image may be analyzed in step 440 to thereby identify said target as comprising at least explosive material.

In one embodiment, this analyzing may comprise comparing said test NIR hyperspectral image to at least one reference hyperspectral image in a reference database wherein each said reference hyperspectral image is associated with a known material. This known material may comprise at least one of: an explosive material, an explosive byproduct material, a concealment material, a non-explosive material, and combinations thereof.

In one embodiment, this comparing may be achieved by applying at least one chemometric technique. This chemometric technique may be selected from the group consisting of: principle component analysis (“PCA”), partial least squares discriminate analysis (“PLSDA”), cosine correlation analysis (“CCA”), Euclidian distance analysis (“EDA”), k-means clustering, multivariate curve resolution (“MCR”), band t. entropy method (“BTEM”), mahalanobis distance (“MD”), adaptive subspace detector (“ASD”), spectral mixture resolution, and combinations thereof. In another embodiment, pattern recognition algorithms may be used.

In another embodiment, illustrated by FIG. 4B, the method 100 may further comprise surveying a region of interest in step 405 to thereby identify a target for further inspection using NIR hyperspectral imaging. This surveying may comprise generating an RGB image of a region of interest. This RGB image may comprise a RGB video image. The RGB image may be inspected by a user to identify a target. This target may be identified, in one embodiment, based on at least one of: size, shape, color, location, or other morphologic feature.

Once a target has been identified for inspection in step 405, a first plurality of photons may be collected in step 410. The first plurality of photons may be passed through a tunable filter in step 420. The first plurality of interacted photons may be detected in step 430 to thereby generate a NIR hyperspectral image representative of said target. This NIR hyperspectral image may then be analyzed in step 440 to thereby identify the target as comprising at least one explosive material.

The NIR hyperspectral image may be displayed for user inspection. This inspection may comprise visual inspection by a user. In one embodiment, this displaying may further comprise the application of one or more pseudo colors to said NIR hyperspectral image. Each pseudo color may be associated with a known material. In one embodiment, two or more pseudo colors may be used to correspond to two or more different materials in said hyperspectral image.

In one embodiment, the use of pseudo colors may comprise technology available from ChemImage Corporation, Pittsburgh, Pa. This technology is more fully described in pending U.S. Patent Application Publication No. US 2011/0012916, filed on Apr. 20, 2010, entitled “System and method for component discrimination enhancement based on multispectral addition imaging,” which is hereby incorporated by reference in its entirety.

In one embodiment, the method 400 may be automated using software. In one embodiment, the invention of the present disclosure may utilize machine readable program code which may contain executable program instructions. A processor may be configured to execute the machine readable program code so as to perform the methods of the present disclosure. In one embodiment, the program code may contain the ChemImage Xpert® software marketed by ChemImage Corporation of Pittsburgh, Pa. The ChemImage Xpert® software may be used to process image and/or spectroscopic data and information received from the portable device of the present disclosure to obtain various spectral plots and images, and to also carry out various multivariate image analysis methods discussed herein.

In one embodiment, the present disclosure provides for a storage medium containing machine readable program code, which, when executed by a processor causes said processor to perform the following: collect a first plurality of interacted photons, wherein said first plurality of interacted photons are selected from the group consisting of: photons absorbed by a target, photons reflected by a target, photons scattered by a target, photons emitted by a target and combinations thereof; pass said first plurality of interacted photons through a tunable filter; detect said first plurality of interacted photons to thereby generate a test NIR hyperspectral image representative of said target; and analyze said test NIR hyperspectral image to thereby identify said target as comprising at least one explosive material, wherein said explosive material comprises at least one of: a bulk explosive material, a gaseous byproduct of an explosive material, and combinations thereof. In one embodiment, said machine readable program code, when executed by a processor, further causes said processor to survey a region of interest to thereby identify said target, wherein said surveying is achieved by generating a video image representative of at least one of said target, said region of interest, and combinations thereof.

In one embodiment, data acquired using two or more modalities may be fused. In one embodiment, NIR data may be fused with RGB data to increase accuracy and reliability of detection. In one embodiment, this fusion may be accomplished using Bayesian fusion. In another embodiment, this fusion may be accomplished using technology available from ChemImage Corporation, Pittsburgh, Pa. This technology is more fully described in the following pending U.S. Patent Applications: No. US2009/0163369, filed on Dec. 19, 2008 entitled “Detection of Pathogenic Microorganisms Using Fused Sensor Data,” No. 13/081,992, filed on Apr. 7, 2011, entitled “Detection of Pathogenic Microorganisms Using Fused Sensor Raman, SWIR and LIBS Sensor Data,” No. US2009/0012723, filed on Aug. 22, 2008, entitled “Adaptive Method for Outlier Detection and Spectral Library Augmentation,” No. US2007/0192035, filed on Jun. 9, 2006, “Forensic Integrated Search Technology,” and No. US2008/0300826, filed on Jan. 22, 2008, entitled “Forensic Integrated Search Technology With Instrument Weight Factor Determination.” These applications are hereby incorporated by reference in their entireties.

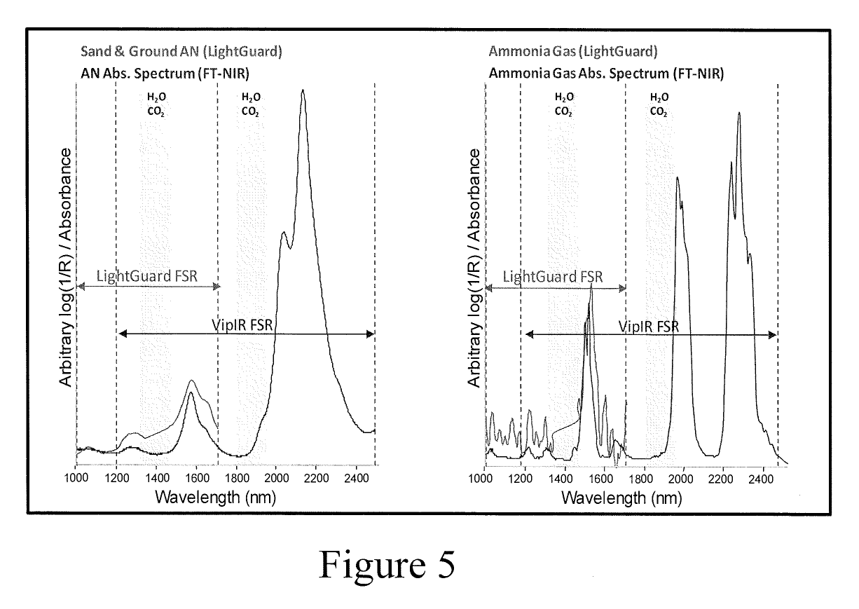

FIG. 5 is provided to illustrate the detection capabilities of a portable device of the present disclosure. As can be seen in the Figure, in the NIR spectral region (approximately 1200 nm-2450 nm), AN absorbance occurs near the 1570 nm and 2200 nm spectral bands. The portable device of the present disclosure hold potential for detecting bulk and out-gassed AN at standoff distances. In one embodiment, these standoff distances may exceed approximately 50 meters, utilizing the 1570 nm spectral band. By analyzing over the 2200 nm spectral band, where absorbance is higher, the portable device of the present disclosure holds potential for increasing detection sensitivity for the detection of AN-based materials.

Based on an area under the curve measurement, the 2200 nm AN peak is 9× larger than the 1570 nm AN peak. The ammonia gas measurement yielded a 5× larger 2000 nm peak when compared to the 1515 nm peak. The system of the present disclosure holds potential for achieving approximately a 9× improvement in detection capability for bulk AN and a 5× improvement in detection capability for gaseous ammonia using the portable device described herein.

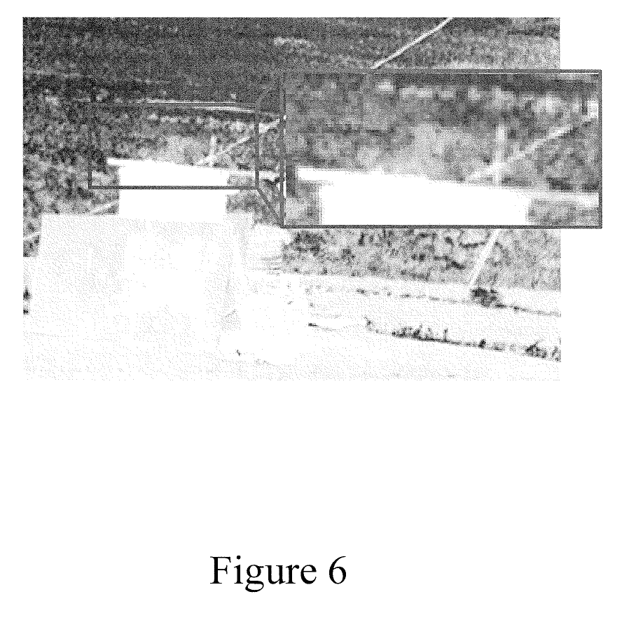

To demonstrate the potential capability for detecting gaseous material, FIG. 6 illustrates the detection of ammonia gas over a barrel being used in the mixing/cooking of ammonium nitrate. The detection of the ammonia gas is shown by the red indicators over the barrel. This detection was made based on the 1570 nm AN peak.

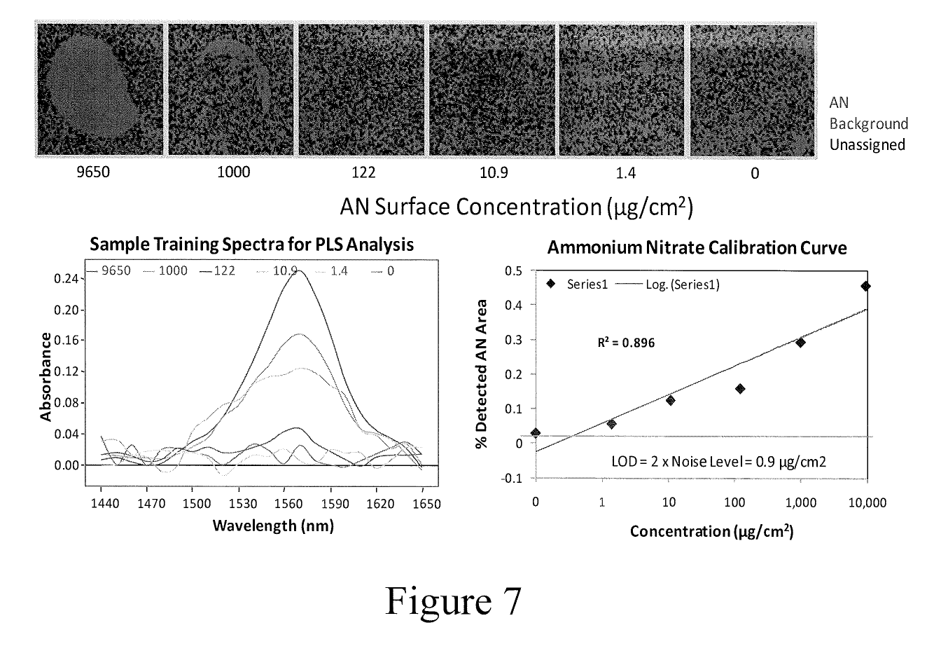

FIG. 7 is illustrative of a limit of detection (LOD) study, focused at the 1570 nm AN absorbance. At the top are the detection images associated with each of the samples prepared for use in the study. Those pixels shown in red correspond to locations where AN has been deposited when evaluated using a partial least squares (PLS) discriminate algorithm, the pixels shown in green correspond to background and the pixels shown in black are unassigned. At the bottom left, the spectra associated with varying concentrations of AN on aluminum are shown. At the bottom right, a calibration curve plotting % Detected AN Area vs log AN Concentration indicates that the LOD for AN on aluminum at 30 m standoff range is 0.9 μg/cm². The limit of detection for bulk AN on surfaces will be improved when analyzing over the 2200 nm spectral band.

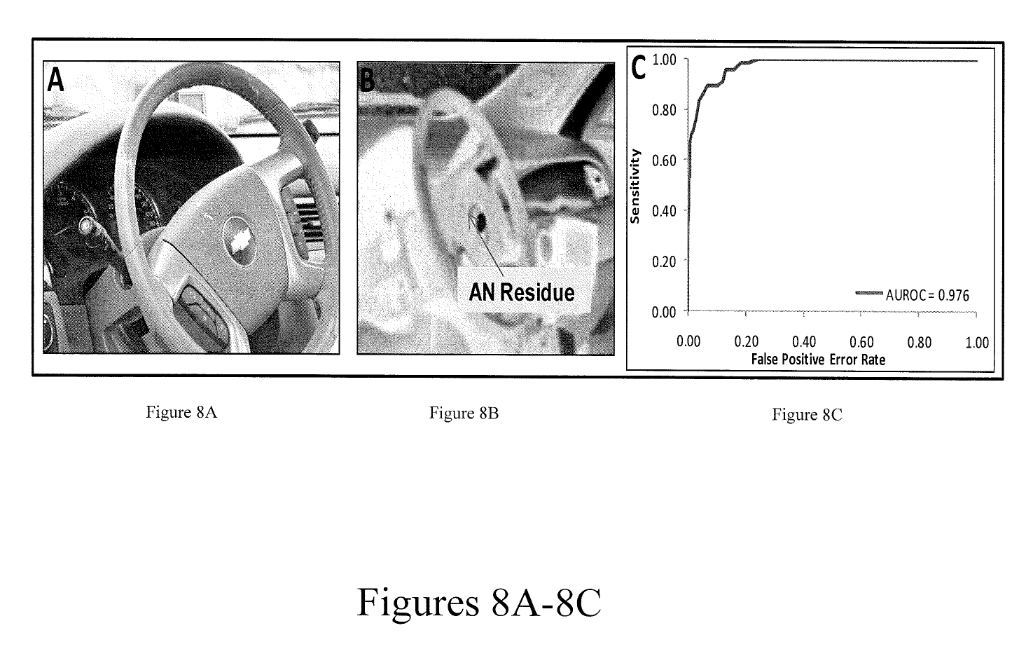

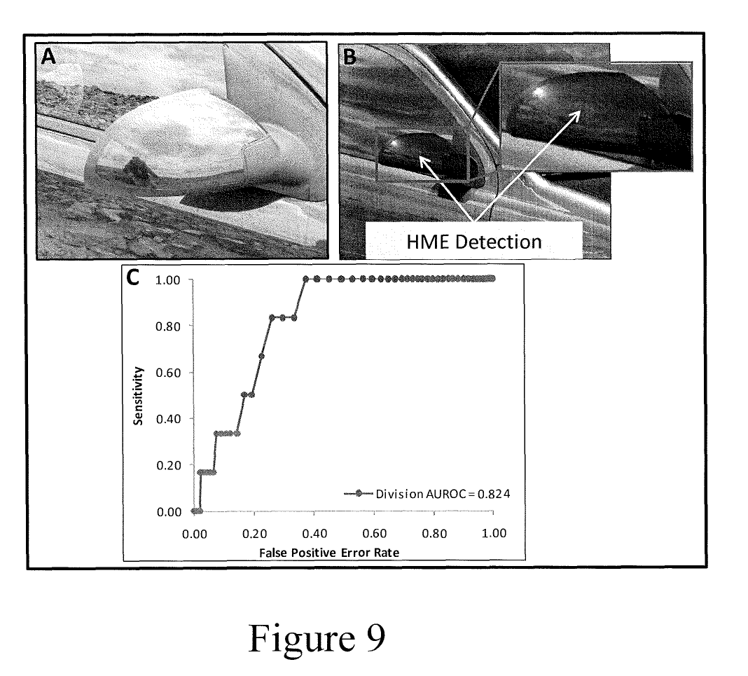

The present disclosure also provides for the use of SWIR HSI for the detection of explosives. This system may be referred to commercially as, the “LightGuard” sensor. This has the potential capability of detecting HMEs under additional “difficult” circumstances, including detection on the inside of a vehicle (FIGS. 8A-8C) and detection of a trace amount on a highly reflective surface (FIG. 9). In FIGS. 8A-8C, the RGB digital image is shown in FIG. 8A, while FIG. 8B is an absorbance image with the arrow denoting the location of AN. FIG. 8C shows the ROC curve associated with this detection.

In FIGS. 9A-9C, a RGB digital image is shown in FIG. 9A, while FIG. 9B shows the detection with the Red marker indicating the presence of an HME material. FIG. 9C shows the ROC curve associated with this detection.

The absorption bands associated with the NIR region of the spectrum generally result from overtones and combination bands of O—H, N—H, C—H and S—H stretching and bending vibrations. The molecular overtones and combination bands in the NIR are typically broad, leading to complex spectra where it can be difficult to assign specific chemical components to specific spectral features. However, by taking advantage of multivariate statistical processing techniques, we can generally extract the important chemical information. With NIR HSI, each pixel in the image has a fully resolved NIR spectrum associated with it, therefore multiple components in the field of view will be distinguishable based on the varying absorption that the materials exhibit at the individual wavelengths. The individual components of interest are uniquely identified based on the absorbance properties.

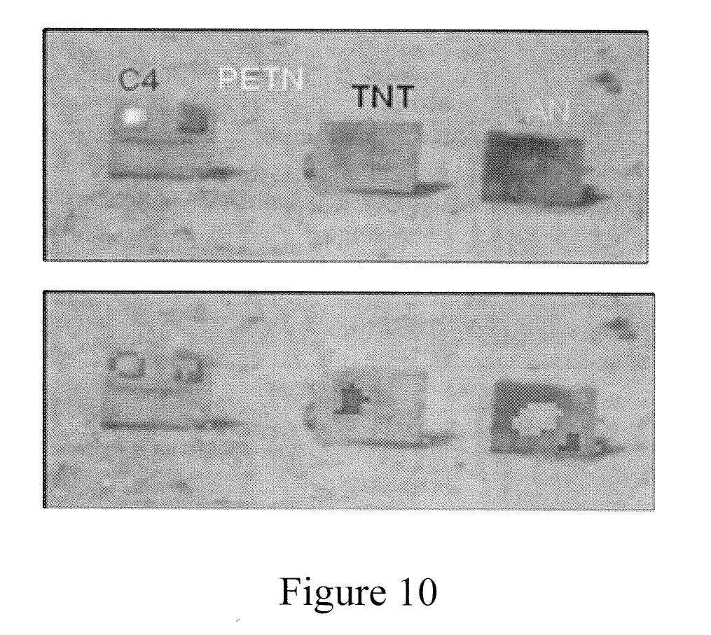

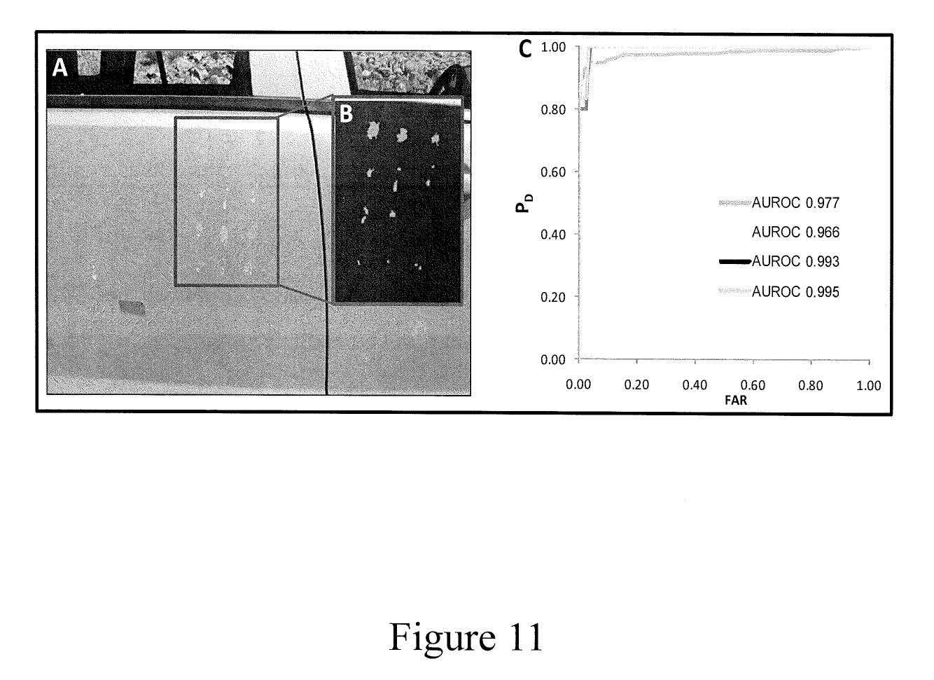

FIGS. 10A-10B shows an example of the stationary detection capabilities for a variety of common explosive residues. The top image (FIG. 10A) in shows a video image of three slate tiles with explosive residues. Detections for each explosive are shown on a pixel-by-pixel basis as false color overlays in FIG. 10B. FIG. 11A shows the detection and identification of several different HMEs containing accelerant with 11B showing the ROC curves for the different HMEs.

In one embodiment, the present disclosure contemplates that the portable device and associated method described herein may be configured for detection of materials other than those associated with explosives. Such materials may include hazardous materials such as biological and/or chemical hazardous agents. The technology disclosed herein may also be configured to detect other materials that may be of interest to areas of border control, entry control points, transportation stations (airport, train station, etc. security stations), or any other security station where detection is critical. For example, the device of the present disclosure may be configured to detect drug or other illegal/contraband substances. The technology may also be configured for operation in forensic applications.

While the disclosure has been described in detail in reference to specific embodiments thereof, it will be apparent to one skilled in the art that various changes and modifications can be made therein without departing from the spirit and scope of the embodiments. Thus, it is intended that the present disclosure cover the modifications and variations of this disclosure provided they come within the scope of the appended claims and their equivalents.

1. A method comprising:
collecting a first plurality of interacted photons generated from at least one target using a portable device, wherein said first plurality of interacted photons are selected from the group consisting of: photons absorbed by a target, photons reflected by a target, photons scattered by a target, photons emitted by a target and combinations thereof;
passing said first plurality of interacted photons through a filter;
detecting said first plurality of interacted photons using said portable device to thereby generate a test NIR hyperspectral image representative of said target;
analyzing said test NIR hyperspectral image to thereby identify said target as comprising at least one a gaseous byproduct of an explosive material.

2. The method of claim 1 wherein said filter comprises a filter selected from the group consisting of: a tunable filter, a fixed filter, a dielectric filter, and combinations thereof.

3. The method of claim 1 wherein said passing said first plurality of interacted photons through said tunable filter further comprises filtering said first plurality of interacted photons in one of the following modalities: sequentially, simultaneously, and combinations thereof.

4. The method of claim 1 further comprising passing said first plurality of interacted photons through a fiber array spectral translator device.

5. The method of claim 1 further comprising generating said first plurality of interacted photons by illuminating said target.

6. The method of claim 5 wherein said illuminating is accomplished using at least one of: active illumination and passive illumination.

7. The method of claim 6 wherein said active illumination is accomplished using an active illumination source, wherein said active illumination source comprises at least one of: a laser light source, a broadband light source, and combinations thereof.

8. The method of claim 6 wherein said passive illumination is accomplished using solar radiation.

9. The method of claim 2 wherein said tunable filter is selected from the group consisting of: a liquid crystal tunable filter, a multi-conjugate tunable filter, an acousto-optical tunable filter, a Lyot liquid crystal tunable filter, an Evans split-element liquid crystal tunable filter, a Solc liquid crystal tunable filter, a ferroelectric liquid crystal tunable filter, a Fabry Perot liquid crystal tunable filter, and combinations thereof.

10. The method of claim 1 further comprising surveying a region of interest using a video capture device to thereby identify said target.

11. The method of claim 10 wherein said surveying comprises generating an RGB image representative of at least one of said target, said region of interest, and combinations thereof.

12. The method of claim 1 wherein said analyzing further comprises comparing said test NIR hyperspectral image to at least one reference NIR hyperspectral image, wherein each said reference NIR hyperspectral image is associated with a known explosive material.

13. The method of claim 12 wherein said comparing is achieved by applying at least one chemometric technique.

14. The method of claim 13 wherein said chemometric technique is selected from the group consisting of: principle components analysis, partial least squares discriminate analysis, cosine correlation analysis, Euclidian distance analysis, k-means clustering, multivariate curve resolution, band t. entropy method, mahalanobis distance, adaptive subspace detector, spectral mixture resolution, and combinations thereof.

15. The method of claim 1 wherein said method is performed at a standoff distance from said target.

16. The method of claim 1 wherein said detecting is achieved using a focal plane array detector.

17. The method of claim 16 wherein focal plane array detector comprises at least one of: an InGaAs focal plane array detector, an InSb focal plane array detector, a MCT focal plane array detector, and combinations thereof.

18. The method of claim 1 wherein said detecting of said first plurality of interacted photons is in at least one of the following ranges: approximately 1200 nm-2450 nm, approximately 900 nm-2450 nm, and combinations thereof.

19. The method of claim 1 further comprising displaying said test NIR hyperspectral image, wherein said displaying is such that said NIR hyperspectral image may be inspected by a user.

20. The method of claim 19 wherein said displaying further comprises applying at least one pseudo color to said test NIR hyperspectral image, wherein each said pseudo color is associated with a known explosive material.

21. The method of claim 1 wherein said collecting, passing, detecting, and analyzing are achieved using the same portable device.

22. A portable device comprising:
a collection optics configured so as to collect a first plurality of interacted photons, wherein said first plurality of interacted photons are selected from the group consisting of:
photons absorbed by a target, photons reflected by a target, photons scattered by a target, photons emitted by a target, and combinations thereof;
a filter configured so as to filter said first plurality of interacted photons;
a first detector, wherein said first detector comprises a NIR detector configured so as to detect said first plurality of interacted photons to thereby generate a test NIR hyperspectral image representative of said target;
at least one processor configured to analyze the NIR hyperspectral image to thereby identify said target as comprising at least one a gaseous byproduct of an explosive material; and
a display for displaying said test NIR hyperspectral image.

23. The portable device of claim 22 wherein said filter comprises a filter selected from the group consisting of: a tunable filter, a fixed filter, a dielectric filter, and combinations thereof.

24. The portable device of claim 22 wherein said filter comprises a tunable filter configured so as to filter said first plurality of interacted photons into a plurality of predetermined wavelength bands.

25. The portable device of claim 22 wherein said filter is configured so as to filter said first plurality of interacted photons in one of the following modalities: sequentially, simultaneously, and combinations thereof.

26. The portable system of claim 22 further comprising a fiber array spectral translator device, wherein said fiber array spectral translator device comprises: a two-dimensional array of optical fibers drawn into a one-dimensional fiber stack so as to effectively convert a two-dimensional field of view into a curvilinear field of view, and wherein said two-dimensional array of optical fibers is configured to receive said photons and transfer said photons out of said fiber array spectral translator device and to at least one of: a spectrometer, a filter, a detector, and combinations thereof.

27. The portable system of claim 22 wherein said NIR detector comprises a focal plane array detector.

28. The portable system of claim 27 wherein said focal plane array detector comprises at least one of: an InGaAs focal plane array detector, an InSb focal plane array detector, a MCT focal plane array detector, and combinations thereof.

29. The portable device of claim 22 wherein said portable device comprises a handheld device.

30. The portable device of claim 22 further comprising an active illumination source, wherein said active illumination source is configured so as to illuminate a target to thereby generate said first plurality of interacted photons.

31. The portable device of claim 30 wherein said active illumination source comprises at least one of: a laser light source, a broadband light source, and combinations thereof.

32. The portable device of claim 22 wherein said portable device is configured for standoff detection.

33. The portable device of claim 22 further comprising a second detector, wherein said second detector is configured so as to generate a RGB image representative of at least one of: said target, a region of interest, and combinations thereof, and wherein said display is further configured to display the RGB image.

34. The portable device of claim 33 wherein said second detector comprises a CMOS RGB detector.

35. The portable device of claim 33 wherein said RGB image comprises an RGB video image.

36. The portable device of claim 22 further comprising at least one embedded processor.

37. The portable device of claim 22 further comprising at least one power source.

38. The portable device of claim 37 wherein said power source comprises at least one battery.

39. The portable device of claim 22 further comprising at least one control configured for controlling operation of said portable device.

40. The portable device of claim 22 wherein said portable device is configured so as to operate using solar radiation.

41. The portable device of claim 22 wherein said portable device is configured for dynamic imaging.

42. The portable device of claim 33 wherein said display is configured so as to display said NIR hyperspectral image and said RGB image simultaneously.

43. The portable device of claim 33 wherein said display is configured so as to display said NIR hyperspectral image and said RGB image sequentially.

44. The portable device of claim 22 wherein said detector is configured so as to operate in at least one of the following ranges: approximately 1200 nm-2450 nm, approximately 900 nm-2450 nm, and combinations thereof.

45. A non-transitory storage medium containing machine readable program code, which, when executed by a processor, causes said processor to perform the following:
collect a first plurality of interacted photons, wherein said first plurality of interacted photons are selected from the group consisting of: photons absorbed by a target, photons reflected by a target, photons scattered by a target, photons emitted by a target and combinations thereof;
pass said first plurality of interacted photons through a tunable filter;
detect said first plurality of interacted photons to thereby generate a test NIR hyperspectral image representative of said target; and
analyze said test NIR hyperspectral image to thereby identify said target as comprising at least one gaseous byproduct of an explosive material.

46. The storage medium of claim 45 wherein said machine readable program code, when executed by a processor, further causes said processor to survey a region of interest to thereby identify said target, wherein said surveying is achieved by generating a video image representative of at least one of said target, said region of interest, and combinations thereof.
